(19) United States
(12) Patent Application Publication
(10) Pub. No.: US 2021/0219452 A1
(43) Pub. Date: Jul. 15, 2021

(54) STAGGERED DRIVE PLACEMENT

(71) Applicant: Quanta Computer Inc., Taoyuan City (TW)

(72) Inventors: Yaw-Tzorng TSORNG, Taoyuan City (TW); Chen-Chien KUO, Taoyuan City (TW); Chin-Ho KUO, Taoyuan City (TW); Jui-Tang CHANG, Taoyuan City (TW)

(21) Appl. No.: 16/742,655

(22) Filed: Jan. 14, 2020

(51) Int. Cl. H05K 7/14

(52) U.S. Cl. CPC H05K 7/1489; G11B 33/04

(57) ABSTRACT

A front-access chassis for storage drives can be configured to store different drives in different orientations in a single group of drives. For example, drives in a disk group can be installed with two vertical drives followed immediately by four horizontal drives. Each chassis can include multiple disk groups. Thus, drives with certain functions can be easily and readily identified based on orientation. For example, system drives may be installed vertically whereas storage drives may be installed horizontally, permitting a user to quickly identify a desired drive at a glance.

### TECHNICAL FIELD

The present disclosure relates to computer hardware generally, and more specifically to chassis and drive placement arrangements in server hardware.

### BACKGROUND

Servers are employed in large numbers for high demand applications such as network based systems or data centers. The emergence of the cloud for computing applications has increased the demand for data centers. Data centers have numerous servers that store data and run applications accessed by remotely connected computer device users. A typical data center has physical chassis structures with attendant power and communication connections. Each rack may hold multiple computing servers and storage servers.

Servers in a single physical chassis may make use of multiple hard drives or other storage devices located in that physical chassis to store an operating system run by that server and any other information that is to be stored and/or served by that server. Such storage devices are traditionally placed in drive bays or otherwise secured to the chassis. Some physical chassis include drive bays at the front of the chassis for easy access to these storage devices, since such storage devices may need to be maintained and/or replaced frequently. Traditional front-access chassis for hard drives include multiple drive bays all oriented in the same direction.

### SUMMARY

The term embodiment and like terms are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter; nor is it intended to be used in isolation to determine the scope of the claimed subject matter. The subject matter should be understood by reference to appropriate portions of the entire specification of this disclosure, any or all drawings and each claim.

Certain embodiments of the present disclosure relate to a chassis. The chassis has a front panel comprising one or more groupings of openings for receiving one or more groupings of storage drives. Each of the one or more groupings of openings comprises a first set of openings oriented to receive a first set of the grouping of storage drives in a horizontal configuration, and a second set of openings oriented to receive a second set of the grouping of storage drives in a vertical configuration.

In some cases, the one or more groupings of openings include at least two groupings of openings. In some cases, the first set of openings includes four openings, and the second set of openings includes two openings. In some cases, the first set of openings includes five openings, and the second set of openings includes one opening. In some cases, the chassis further comprises connectors to couple each of the one or more groupings of storage drives to a respective one of one or more mainboards. In some cases, the second set of the grouping of storage drives is used to store an operating system of a mainboard associated with the grouping of storage drives, and the first set of the grouping of storage drives is not used to store the operating system.

Certain embodiments of the present disclosure relate to a system comprising one or more mainboards deployed in a chassis. The embodiment also includes one or more groupings of storage drives deployed in the chassis and coupled to the one or more mainboards. Each of the one or more groupings of storage drives comprises a first set of the grouping of storage drives deployed in the chassis in a horizontal configuration, and a second set of the grouping of storage drives deployed in the chassis in a vertical configuration.

In some cases, the one or more groupings of storage drives comprises at least two groupings of storage drives. In some cases, the first set of the grouping of storage drives includes four storage drives, and the second set of the grouping of storage drives includes two storage drives. In some cases, the first set of the grouping of storage drives includes five storage drives, and the second set of the grouping of storage drives includes one storage drive. In some cases, each of the one or more groupings of storage drives is coupled to a respective one of the one or more mainboards. In some cases, the second set of the grouping of storage drives is used to store an operating system of at least one of the one or more mainboards, and the first set of the grouping of storage drives is not used to store the operating system.

Certain embodiments of the present disclosure relate to a method in which a chassis is provided. One or more mainboards are installed in the chassis. One or more groupings of storage drives are installed in the chassis. Installing a grouping of storage drives in a chassis comprises installing a first set of the grouping of storage drives in the chassis in a horizontal configuration. A second set of the grouping of storage drives is installed in the chassis in a vertical configuration. The grouping of storage drives is coupled to the one or more mainboards of the chassis.

In some cases, installing one or more groupings of storage drives in the chassis comprises installing at least two groupings of storage drives in the chassis. In some cases, the first set of the grouping of storage drives includes four storage drives, and the second set of the grouping of storage drives includes two storage drives. In some cases, the first set of the grouping of storage drives includes five storage drives, and the second set of the grouping of storage drives includes one storage drive. In some cases, coupling the grouping of storage drives to the one or more mainboards of the chassis comprises coupling the grouping of storage drives to one of the one or more mainboards that is associated with the grouping of storage drives. In some cases, the method further comprises running an operating system on the one or more mainboards using the second set of the grouping of storage drives. The operating system is stored on the second set of the grouping of storage drives, and the first set of the grouping of storage drives is not used to store the operating system.

### BRIEF DESCRIPTION OF THE DRAWINGS

The specification makes reference to the following appended figures, in which use of like reference numerals in different figures is intended to illustrate like or analogous components.

FIG. 1 is a front view of a server chassis, according to certain aspects of the present disclosure.

FIG. 2 is a front view of a server chassis with four horizontal drives and two vertical drives in each drive group, according to certain aspects of the present disclosure.

FIG. 3 is a schematic diagram of a server using a chassis with four horizontal drives and two vertical drives in each drive group, according to certain aspects of the present disclosure.

FIG. 4 is a front view of a server chassis with two vertical drives and four horizontal drives in each drive group, according to certain aspects of the present disclosure.

FIG. 5 is a front view of a server chassis with one vertical drive and five horizontal drives in each drive group, according to certain aspects of the present disclosure.

FIG. 6 is a front view of a server chassis with five horizontal drives and one vertical drives in each drive group, according to certain aspects of the present disclosure.

FIG. 7 is a flowchart depicting a process for using a staggered drive arrangement, according to certain aspects of the present disclosure.

### DETAILED DESCRIPTION

The present disclosure relates to a staggered placement of storage devices, such as hard drives, in a computer chassis, such as a front-access chassis. The staggered placement can facilitate rapid identification and organization of storage devices by orientation. For example, a computer server coupled to an array of drives may be coupled to an array of four horizontally mounted drives and an array of two vertically mounted drives. The four horizontally mounted drives may be used for storage for data to be stored and/or served, whereas the two vertical mounted drives may be used to house the operating system and/or other data associated with the operation of the underlying operating system miming on the computer server. A single chassis can have multiple arrays of drives, such as one for each computer (e.g., motherboard) within the chassis. In some cases, staggered placement can provide other benefits associated with alternating between a set of horizontal drives and a set of vertical drives within a chassis.

In some cases, it can be important to be able to quickly and reliably identify a drive's purpose at a glance for a front-access chassis system. For example, when swapping hard drives in a chassis, it can be helpful to know that certain drives with an operating pre-installed can be placed in certain drive bays associated with system drives, whereas empty drives may be placed in certain drive bays associated with storage drives. Thus, certain maintenance and installation tasks can be performed more reliably and faster, thus minimizing downtime at a datacenter.

A chassis suitable for staggered drive placement, as disclosed herein, can include openings or drive bays in desired orientations. Further, any necessary storage boards and/or linking boards can be installed in the chassis to facilitate connection of storage devices inserted into the drive bays.

A chassis can have one or more groupings of openings, each having two or more sets of openings, at least one set arranged in a horizontal configuration (e.g., to support a drive in an orientation parallel a bottom of a chassis) and at least another set arranged in a vertical configuration (e.g., to support a drive in an orientation perpendicular a bottom of a chassis). In some cases, additional sets of openings can be used, such as a third set of openings, to provide a second horizontal or vertical set of openings. Generally, however, each grouping of openings will have only a first set of openings and a second set of openings.

In some cases, an especially useful arrangement for a typical server (e.g., a two rack unit or 2U server) can include four groupings of openings with each grouping containing a first set of four openings in a horizontal configuration, and a second set of two openings in a vertical configuration. In some cases, an especially useful arrangement for a typical server (e.g., a two rack unit or 2U server) can include four groupings of openings, with each grouping containing a first set of two openings in a vertical configuration, and a second set of four openings in a horizontal configuration. In some cases, an especially useful arrangement for a typical server (e.g., a two rack unit or 2U server) can include four groupings of openings with each grouping containing a first set of five openings in a horizontal configuration, and a second set of a single opening in a vertical configuration. In some cases, an especially useful arrangement for a typical server (e.g., a two rack unit or 2U server) can include four groupings of openings, with each grouping containing a first set of a single opening in a vertical configuration, and a second set of five openings in a horizontal configuration.

These illustrative examples are given to introduce the reader to the general subject matter discussed here and are not intended to limit the scope of the disclosed concepts. The following sections describe various additional features and examples with reference to the drawings in which like numerals indicate like elements, and directional descriptions are used to describe the illustrative embodiments but, like the illustrative embodiments, should not be used to limit the present disclosure. The elements included in the illustrations herein may not be drawn to scale.

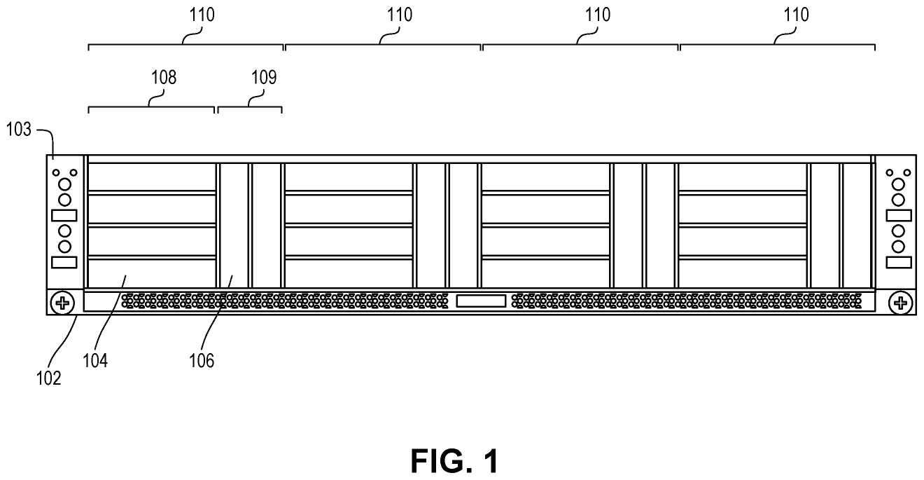

FIG. 1 is a front view of a server chassis 102, according to certain aspects of the present disclosure. The server chassis 102 can have a front panel 103 with one or more groupings 110 of openings (e.g., drive bays). The server chassis 102 is depicted with four groupings 110, however any suitable number can be used. Each grouping 110 can include a first set of openings 108 and a second set of openings 109, one of which contains openings configured for horizontal drive placement, the other of which contains openings configured for vertical drive placement. As depicted in FIG. 1, the first set of openings 108 contains openings 104 oriented to receive storage drives in a horizontal configuration, and the second set of openings 109 contains openings 106 oriented to receive storage drives in a vertical configuration.

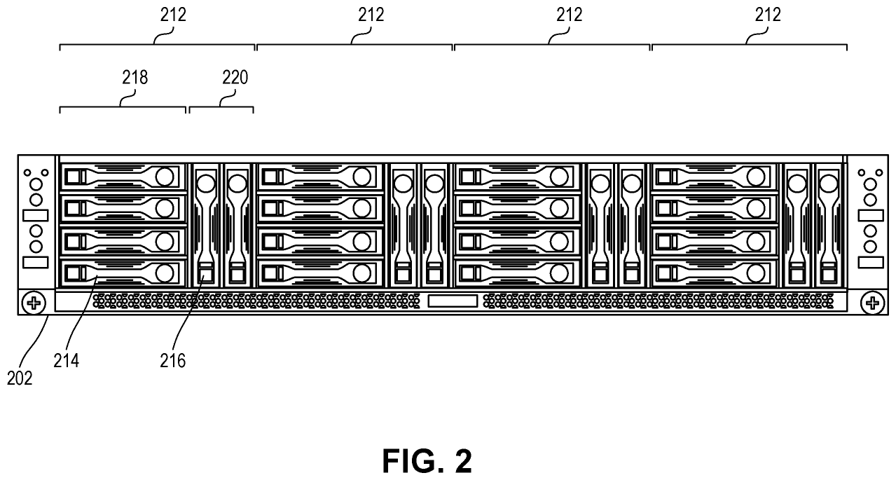

FIG. 2 is a front view of a server chassis 202 with four horizontal drives 214 and two vertical drives 216 in each drive group 212, according to certain aspects of the present disclosure. The server chassis 202 can be server chassis 102 of FIG. 1 after insertion of storage drives, such as hard drives. The server chassis 202 can include one or more drive groups 212, such as four drive groups 212, each associated with a grouping of openings (e.g., groupings 112 of FIG. 1).

Each drive group 212 can include a first set of drives 218 and a second set of drives 220; one of which contains drives in a horizontal orientation, and the other of which contains drives in a vertical orientation. As depicted in FIG. 2, the first set of drives 218 contains drives 214 in a horizontal orientation, and the second set of drives 220 contains drives 216 in a vertical orientation.

In some cases, each drive group 212 can be associated with a respective motherboard (e.g., mainboard) within chassis 202. For each motherboard, and thus for each drive group 212, the second set of drives 220 can contain operating system data associated with an operating system running on the motherboard. Operating system data can be the operating system or other information usable to operate the operating system. By contrast, the first set of drives 218 for each drive group 212 can be used to contain data stored or served by the motherboard. In some cases, the first set of drives 218 for each drive group 212 can be used for data that is not operating system data. Other arrangements and organizational schemes for data can be used.

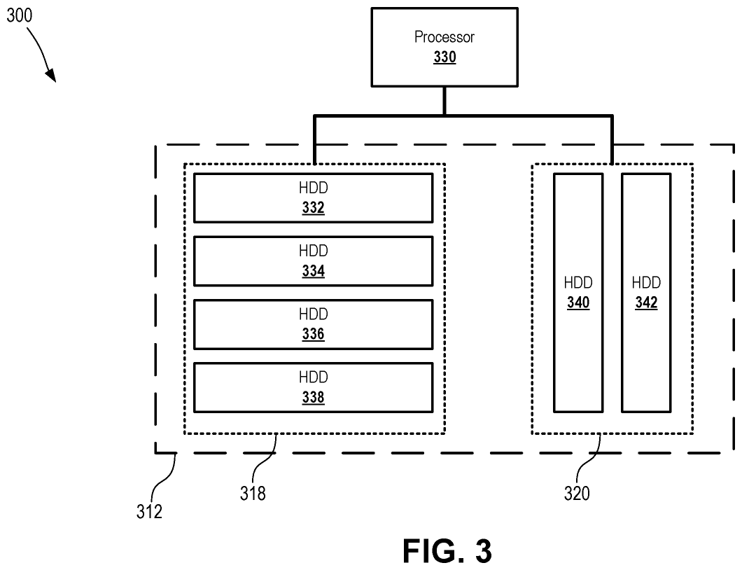

FIG. 3 is a schematic diagram of a server 300 using a chassis with four horizontal drives 332, 334, 336, 338 and two vertical drives 340, 342 in each drive group 312, according to certain aspects of the present disclosure. Server 300 can be the server associated with chassis 202 of FIG. 2. Each chassis can contain one or more drive groups 312. In some cases, each drive group 312 can be associated with a processor 330 on a motherboard coupled to the drives 332, 334, 336, 338, 340, 342 of the drive group 312. In some cases, multiple processors can be used. In some cases, additional drive groups can be coupled to processor 330.

Each drive group 312 can include a first set of drives 318 and a second set of drives 320; one of which contains drives in a horizontal orientation, and the other of which contains drives in a vertical orientation. As depicted in FIG. 3, the first set of drives 318 contains drives 332, 334, 336, 338 in a horizontal orientation, and the second set of drives 320 contains drives 340, 342 in a vertical orientation.

In some cases, each drive group 312 can be associated with a respective motherboard, and each drive group 312 can be associated with a processor 330. For each motherboard, and thus for each drive group 312, the second set of drives 320 can contain operating system data associated with an operating system running on the motherboard, and thus running on processor 330. Operating system data can be the operating system or other information usable to operate the operating system. By contrast, the first set of drives 318 for each drive group 312 can be used to contain data stored or served by the motherboard. In some cases, the first set of drives 318 for each drive group 312 can be used for data that is not operating system data. Other arrangements and organizational schemes for data can be used.

In some cases, as disclosed herein, the number of drives in the first set of drives 318 and/or the number of drives in the second set of drives 320 can differ. In some especially useful arrangements, the first set of drives 318 can contain four drives, and the second set of drives 320 can contain two drives. In some especially useful arrangements, the first set of drives 318 can contain five drives and the second set of drives 320 can contain one drive.

While the first set of drives 318 are depicted to the left of the second set of drives 320 in FIG. 3, that need not always be the case. In some cases, the second set of drives 320 can be located to the left of the first set of drives 318, such as disclosed in further detail herein.

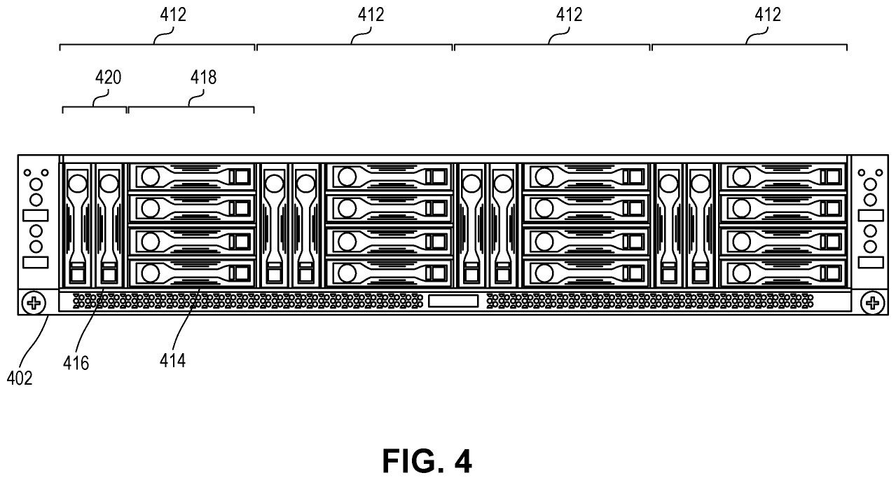

FIG. 4 is a front view of a server chassis with two vertical drives 416 and four horizontal drives 414 in each drive group 412, according to certain aspects of the present disclosure. The server chassis 402 can be similar to server chassis 102 of FIG. 1, but with a different arrangement of openings and after insertion of storage drives, such as hard drives. The server chassis 402 can include one or more drive groups 412, such as four drive groups 412, each associated with a grouping of openings (e.g., groupings 112 of FIG. 1).

Each drive group 412 can include a first set of drives 420 and a second set of drives 418; one of which contains drives in a horizontal orientation, and the other of which contains drives in a vertical orientation. As depicted in FIG. 4, the first set of drives 420 contains drives 416 in a vertical orientation, and the second set of drives 418 contains drives 414 in a horizontal orientation.

In some cases, each drive group 412 can be associated with a respective motherboard within the server chassis 402. For each motherboard, and thus for each drive group 412, the first set of drives 420 can contain operating system data associated with an operating system running on the motherboard. Operating system data can be the operating system or other information usable to operate the operating system. By contrast, the second set of drives 418 for each drive group 412 can be used to contain data stored or served by the motherboard. In some cases, the second set of drives 418 for each drive group 412 can be used for data that is not operating system data. Other arrangements and organizational schemes for data can be used.

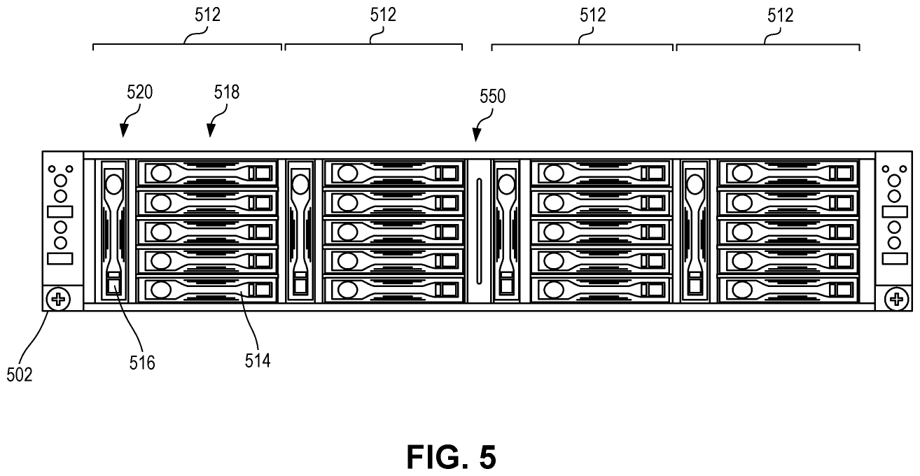

FIG. 5 is a front view of a server chassis 502 with one vertical drive 516 and five horizontal drives 514 in each drive group 512, according to certain aspects of the present disclosure. The server chassis 502 can be similar to server chassis 102 of FIG. 1, but with a different arrangement of openings and after insertion of storage drives, such as hard drives. The server chassis 502 can include one or more drive groups 512, such as four drive groups 512, each associated with a grouping of openings (e.g., groupings 112 of FIG. 1).

Each drive group 512 can include a first set of drives 520 and a second set of drives 518; one of which contains drives in a horizontal orientation, and the other of which contains drive(s) in a vertical orientation. As used herein, the term “set of drives” can be inclusive of a single drive. As depicted in FIG. 5, the first set of drives 520 contains a single drive 516 in a vertical orientation, and the second set of drives 518 contains drives 514 in a horizontal orientation.

In some cases, each drive group 512 can be associated with a respective motherboard within the server chassis 502. For each motherboard, and thus for each drive group 512, the first set of drives 520 (e.g., drive 516) can contain operating system data associated with an operating system running on the motherboard. Operating system data can be the operating system or other information usable to operate the operating system. By contrast, the second set of drives 518 for each drive group 512 can be used to contain data stored or served by the motherboard. In some cases, the second set of drives 518 for each drive group 512 can be used for data that is not operating system data. Other arrangements and organizational schemes for data can be used.

In some cases, the arrangement of drives within the drive groups 512 can permit additional components 550 to be set into the chassis. For example, in a 2U chassis with four drive groups 512, each having a single vertical drive 516 and five horizontal drives 514, space for an additional component 550 can be found between one or more of the drive groups 512. This additional component 550 can be an additional drive, a memory device, an input/output device, an input/output interface, or any other suitable component.

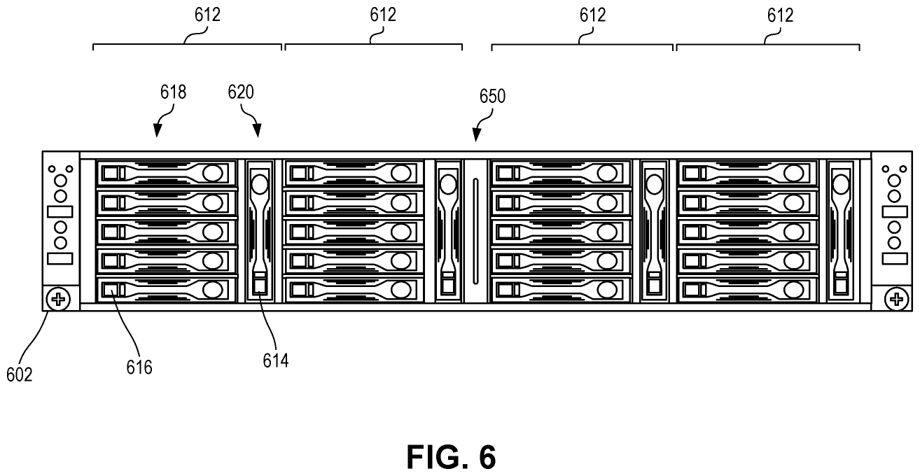

FIG. 6 is a front view of a server chassis 602 with five horizontal drives 616 and one vertical drive 614 in each drive group 612, according to certain aspects of the present disclosure. The server chassis 602 can be similar to server chassis 102 of FIG. 1, but with a different arrangement of openings and after insertion of storage drives, such as hard drives. The server chassis 602 can include one or more drive groups 612, such as four drive groups 612, each associated with a grouping of openings (e.g., groupings 112 of FIG. 1).

Each drive group 612 can include a first set of drives 618 and a second set of drives 620; one of which contains drives in a horizontal orientation, and the other of which contains drive(s) in a vertical orientation. As used herein, the term “set of drives” can be inclusive of a single drive. As depicted in FIG. 6, the first set of drives 618 contains drives 616 in a horizontal orientation, and the second set of drives 620 contains a single drive 614 in a vertical orientation.

In some cases, each drive group 612 can be associated with a respective motherboard within the server chassis 602. For each motherboard, and thus for each drive group 612, the second set of drives 620 (e.g., drive 614) can contain operating system data associated with an operating system running on the motherboard. Operating system data can be the operating system or other information usable to operate the operating system. By contrast, the first set of drives 618 for each drive group 612 can be used to contain data stored or served by the motherboard. In some cases, the first set of drives 618 for each drive group 612 can be used for data that is not operating system data. Other arrangements and organizational schemes for data can be used.

In some cases, the arrangement of drives within the drive groups 612 can permit additional components 650 to be set into the chassis. For example, in a 2U chassis with four drive groups 612, each having a single vertical drive 614 and five horizontal drives 616, space for an additional component 650 can be found between one or more of the drive groups 612. This additional component 650 can be an additional drive, a memory device, an input/output device, an input/output interface, or any other suitable component.

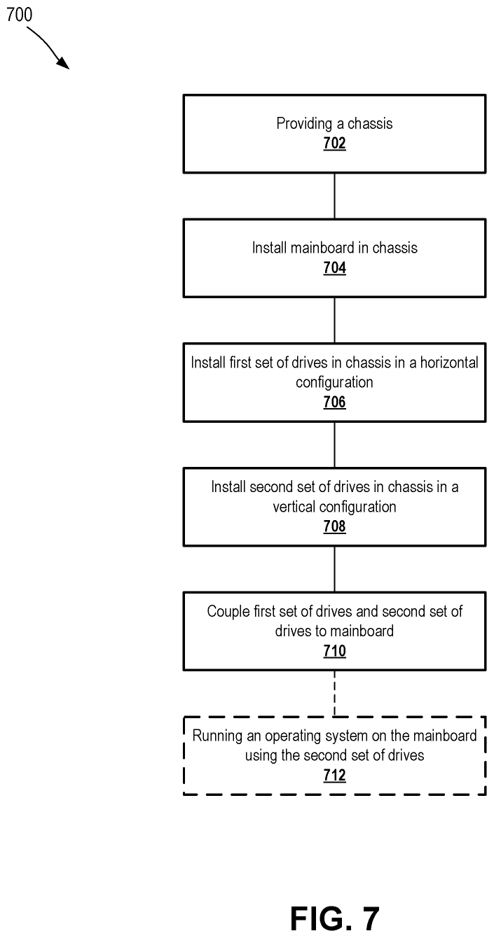

FIG. 7 is a flowchart depicting a process 700 for using a staggered drive arrangement according to certain aspects of the present disclosure. The process 700 can involve using the server chassis 102 of FIG. 1 or any other chassis as disclosed herein. At step 702, a chassis can be provided.

At step 704, a mainboard (e.g., motherboard) can be installed in the chassis. At step 706, a first set of drives can be installed into the chassis in a horizontal configuration. At step 708, a second set of drives can be installed into the chassis in a vertical configuration. At step 710, the first set of drives and the second set of drives can be coupled to the mainboard.

At optional step 712, an operating system can be run on the mainboard using the second set of drives.

In some cases, steps 704, 706, 708, 710, and optionally step 712, can be repeated for multiple mainboards and/or disk groups in a system.

The foregoing description of the embodiments, including illustrated embodiments, has been presented only for the purpose of illustration and description and is not intended to be exhaustive or limiting to the precise forms disclosed. Numerous modifications, adaptations, and uses thereof will be apparent to those skilled in the art.

What is claimed is:

1. A chassis, comprising:
a front panel comprising one or more groupings of openings for receiving one or more groupings of storage drives, wherein each of the one or more groupings of openings comprises:
a first set of openings oriented to receive a first set of the grouping of storage drives in a horizontal configuration; and
a second set of openings oriented to receive a second set of the grouping of storage drives in a vertical configuration.

2. The chassis of claim 1, wherein the one or more groupings of openings comprises at least two groupings of openings.

3. The chassis of claim 1, wherein the first set of openings includes four openings, and wherein the second set of openings includes two openings.

4. The chassis of claim 1, wherein the first set of openings includes five openings, and wherein the second set of openings includes one opening.

5. The chassis of claim 1, further comprising connectors to couple each of the one or more groupings of storage drives to a respective one of one or more mainboards.

6. The chassis of claim 1, wherein the second set of the grouping of storage drives is used to store an operating system of a mainboard associated with the grouping of storage drives, and wherein the first set of the grouping of storage drives is not used to store the operating system.

7. A system, comprising:
one or more mainboards deployed in a chassis;
one or more groupings of storage drives deployed in the chassis and coupled to the one or more mainboards, wherein each of the one or more groupings of storage drives comprises:
a first set of the grouping of storage drives deployed in the chassis in a horizontal configuration; and
a second set of the grouping of storage drives deployed in the chassis in a vertical configuration.

8. The system of claim 7, wherein the one or more groupings of storage drives comprises at least two groupings of storage drives.

9. The system of claim 7, wherein the first set of the grouping of storage drives includes four storage drives, and wherein the second set of the grouping of storage drives includes two storage drives.

10. The system of claim 7, wherein the first set of the grouping of storage drives includes five storage drives, and wherein the second set of the grouping of storage drives includes one storage drive.

11. The system of claim 7, wherein each of the one or more groupings of storage drives is coupled to a respective one of the one or more mainboards.

12. The system of claim 7, wherein the second set of the grouping of storage drives is used to store an operating system of at least one of the one or more mainboards, and wherein the first set of the grouping of storage drives is not used to store the operating system.

13. A method, comprising:
providing a chassis;
installing one or more mainboards in the chassis;
installing one or more groupings of storage drives in the chassis, wherein installing a grouping of storage drives in a chassis comprises:
installing a first set of the grouping of storage drives in the chassis in a horizontal configuration;
installing a second set of the grouping of storage drives in the chassis in a vertical configuration; and
coupling the grouping of storage drives to the one or more mainboards of the chassis.

14. The method of claim 13, wherein installing one or more groupings of storage drives in the chassis comprises installing at least two groupings of storage drives in the chassis.

15. The method of claim 13, wherein the first set of the grouping of storage drives includes four storage drives, and wherein the second set of the grouping of storage drives includes two storage drives.

16. The method of claim 13, wherein the first set of the grouping of storage drives includes five storage drives, and wherein the second set of the grouping of storage drives includes one storage drive.

17. The method of claim 13, wherein coupling the grouping of storage drives to the one or more mainboards of the chassis comprises coupling the grouping of storage drives to one of the one or more mainboards that is associated with the grouping of storage drives.

18. The method of claim 13, further comprising running an operating system on the one or more mainboards using the second set of the grouping of storage drives, wherein the operating system is stored on the second set of the grouping of storage drives, and wherein the first set of the grouping of storage drives is not used to store the operating system.
